(19) United States
(12) Patent Application Publication
(10) Pub. No.: US 2019/0210122 A1
(43) Pub. Date: Jul. 11, 2019

(54) CUTTING TOOL FOR SPUTTERING TARGET, PROCESSING METHOD OF SPUTTERING TARGET, AND MANUFACTURING METHOD OF SPUTTERING TARGET PRODUCT

(71) Applicant: SUMITOMO CHEMICAL COMPANY, LIMITED, Tokyo (JP)

(72) Inventor: Masahiro FUJITA, Niihama-shi (JP)

(73) Assignee: SUMITOMO CHEMICAL COMPANY, LIMITED, Tokyo (JP)

(21) Appl. No.: 16/332,194

(22) PCT Filed: Feb. 9, 2018
(86) PCT No.: PCT/JP2018/004577

§ 371 Date: Mar. 11, 2019

(30) Foreign Application Priority Data
Feb. 16, 2017 (JP) 2017-027091
Nov. 21, 2017 (JP) 2017-223329

(51) Int. Cl. B23C 3/12; C23C 14/34; B23C 3/04; B23C 5/12

(52) U.S. Cl. CPC B23C 3/12; B23C 5/12; B23C 3/04; C23C 14/3407

(57) ABSTRACT

Provided is a cutting tool for a sputtering target that is used to chamfer a corner portion formed between a sputtering surface and a side surface of a sputtering target, into an R plane, the cutting tool comprising:
a shaft portion; and a blade portion provided at a tip end of the shaft portion, wherein
as viewed from a cross section along an axis of the shaft portion, the blade portion includes: a side surface extending along the axis;
a leading end surface intersecting the axis; a main concave curved surface positioned between the side surface and the leading end surface, the main concave curved surface extending from a trailing end to a leading end; a first notched surface connected between the leading end of the main concave curved surface and the leading end surface; and a second notched surface connected between the trailing end of the main concave curved surface and the side surface.

### TECHNICAL FIELD

The present invention relates to a cutting tool for a sputtering target, a processing method of a sputtering target, and a manufacturing method of a sputtering target product.

### BACKGROUND ART

Conventionally, in a sputtering target, a corner portion formed between a sputtering surface and a side surface thereof is chamfered into an R plane by machining (see Patent Document 1).

### PRIOR ART DOCUMENT

### Patent Document

Patent Document 1: JP 2001-40471 A

### DISCLOSURE OF THE INVENTION

### Problems to be Solved by the Invention

The inventors of the present application have found that the R plane is scratched when chamfering the corner portion of the sputtering target. Such a scratch may cause abnormal discharge when sputtering is performed for film deposition onto a substrate, that is, when a high voltage is applied between the substrate and the sputtering target. For this reason, the chamfering of the corner portion of the sputtering target needs to be performed with high accuracy.

The present invention provides a cutting tool for a sputtering target, a processing method of a sputtering target, and a manufacturing method of a sputtering target product, which are less likely to cause scratches when a corner portion of the sputtering target is chamfered into an R plane.

### Means for Solving the Problems

A cutting tool for a sputtering target of the present invention is used to chamfer a corner portion formed between a sputtering surface and a side surface of a sputtering target, into an R plane, the cutting tool for a sputtering target comprising:

a shaft portion; and a blade portion provided at a tip end of the shaft portion, wherein

as viewed from a cross section along an axis of the shaft portion, the blade portion includes: a side surface extending along the axis; a leading end surface intersecting the axis; a main concave curved surface positioned between the side surface and the leading end surface, the main concave curved surface extending from a trailing end to a leading end; a first notched surface connected between the leading end of the main concave curved surface and the leading end surface; and a second notched surface connected between the trailing end of the main concave curved surface and the side surface.

As used herein, the expression “side surface extending along the axis” includes a state in which the side surface is in parallel to the axis and a state in which the side surface intersects the axis without being perpendicular to the axis.

In the cutting tool for a sputtering target of the present invention, as viewed from the cross section along the axis, the blade portion includes the side surface, the leading end surface, the main concave curved surface, the above-mentioned first notched surface, and the above-mentioned second notched surface.

In an embodiment of the cutting tool for a sputtering target, the cutting tool is proposed wherein, as viewed from the cross section along the axis of the shaft portion, the first notched surface includes a first sub-convex curved surface or a first inclined surface that is connected to the leading end of the main concave curved surface, and the second notched surface includes a second sub-convex curved surface or a second inclined surface that is connected to the trailing end of the main concave curved surface.

The concave curved surface and the convex curved surface include not only a perfectly circular arc surface, but also an elliptical arc surface.

In another embodiment of the cutting tool for a sputtering target, as viewed from the cross section along the axis of the shaft portion, the first notched surface includes the first sub-convex curved surface connected to the leading end of the main concave curved surface, and the second notched surface includes the second sub-convex curved surface connected to the trailing end of the main concave curved surface.

According to the above-mentioned embodiment, when the corner portion of the sputtering target is chamfered into the R plane by cutting with the main concave curved surface, both ends of the main concave curved surface become the first and second sub-convex curved surfaces, thereby making it possible to prevent the formation of scratches on the R plane.

In another embodiment of the cutting tool for a sputtering target, as viewed from the cross section along the axis, the first notched surface further includes a third sub-concave curved surface connected to a leading end of the first sub-convex curved surface, and the second notched surface further includes a fourth sub-concave curved surface connected to a leading end of the second sub-convex curved surface.

According to the above-mentioned embodiment, the first notched surface further includes the third sub-concave curved surface connected to the leading end of the first sub-convex curved surface, and the second notched surface further includes the fourth sub-concave curved surface connected to the leading end of the second sub-convex curved surface. This configuration can more reliably prevent the formation of scratches on the R plane, as well as the occurrence of abnormal discharge because the angle of the R plane formed relative to the sputtering target surface is closer to a flat angle.

In another embodiment of the cutting tool for a sputtering target, as viewed from the cross section along the axis of the shaft portion, the first notched surface includes a first inclined surface connected to the leading end of the main concave curved surface, and the second notched surface includes a second inclined surface connected to the trailing end of the main concave curved surface.

According to the above-mentioned embodiment, the formation of scratches on the R plane can be prevented.

In an embodiment of a processing method of a sputtering target of the invention, the processing method involves chamfering a corner portion formed between a sputtering surface and a side surface of the sputtering target, into an R plane, wherein

the corner portion is chamfered into the R plane through cutting by bringing an outer circumferential surface of the blade portion of the above-mentioned cutting tool for a sputtering target into contact with the corner portion of the sputtering target, while rotating the cutting tool about an axis of the shaft portion.

According to the above-mentioned embodiment, the sputtering target is processed using the aforesaid cutting tool for the sputtering target, thereby making it possible to prevent the formation of scratches on the R plane of the sputtering target.

In another embodiment of the processing method of a sputtering target,

the corner portion is chamfered into the R plane through cutting by bringing an outer circumferential surface of the blade portion of the above-mentioned cutting tool for a sputtering target into contact with the corner portion of the sputtering target, while rotating the sputtering target.

According to the above-mentioned embodiment, the sputtering target is processed using the aforesaid cutting tool for the sputtering target, thereby making it possible to prevent the formation of scratches on the R plane of the sputtering target.

In an embodiment of a manufacturing method of a sputtering target product,

the manufacturing method comprises a step of processing a sputtering target by the above-mentioned processing method.

According to the above-mentioned embodiment, the sputtering target product is manufactured by the aforesaid processing method of the sputtering target, whereby the sputtering target product having improved quality can be obtained.

In another embodiment of the manufacturing method of a sputtering target product,

the manufacturing method comprises a step of processing a disk-shaped or cylindrical sputtering target by the above-mentioned processing method.

According to the embodiment, the sputtering target product having improved quality can be obtained.

### Effects of the Invention

According to the cutting tool for a sputtering target of the present invention, scratches are less likely to be formed on an R plane when the corner portion of the sputtering target is chamfered into the R plane.

According to the processing method of a sputtering target of the present invention, the formation of scratches on the R plane of the sputtering target can be prevented.

According to the manufacturing method of a sputtering target product of the present invention, the sputtering target product that is less likely to cause abnormal discharge during use can be obtained.

### BRIEF DESCRIPTION OF THE DRAWINGS

FIG. 1 is a perspective view showing an operation of a first embodiment of a cutting tool for a sputtering target of the present invention.

FIG. 2 is a cross-sectional view showing the operation of the cutting tool for a sputtering target.

FIG. 3 is an enlarged cross-sectional view of FIG. 2.

FIG. 4 is a cross-sectional view showing an operation of a cutting tool for a sputtering target as a comparative example.

FIG. 5 is a cross-sectional view showing an operation of a second embodiment of the cutting tool for a sputtering target of the present invention.

FIG. 6 is a cross-sectional view showing another operation of the second embodiment of the cutting tool for a sputtering target of the present invention.

FIG. 7 is a cross-sectional view showing an operation of a third embodiment of a cutting tool for a sputtering target of the present invention.

### MODE FOR CARRYING OUT THE INVENTION

The present invention will be described in detail below with reference to embodiments shown in the accompanying drawings.

### First Embodiment

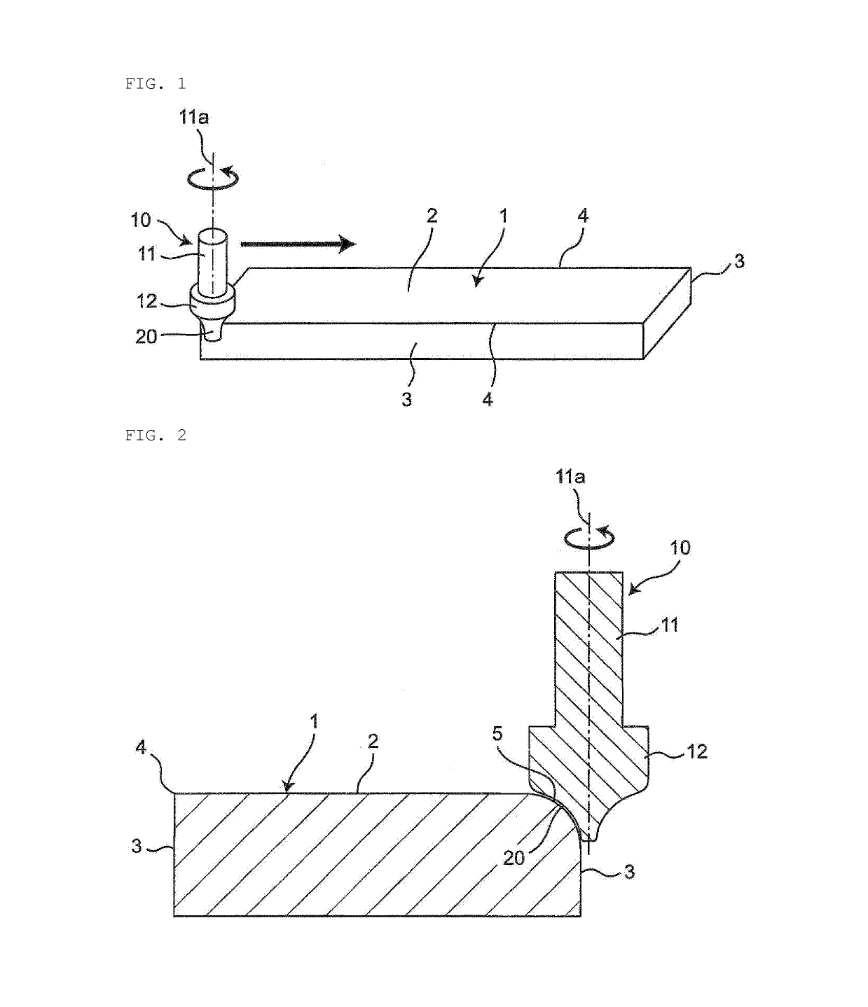

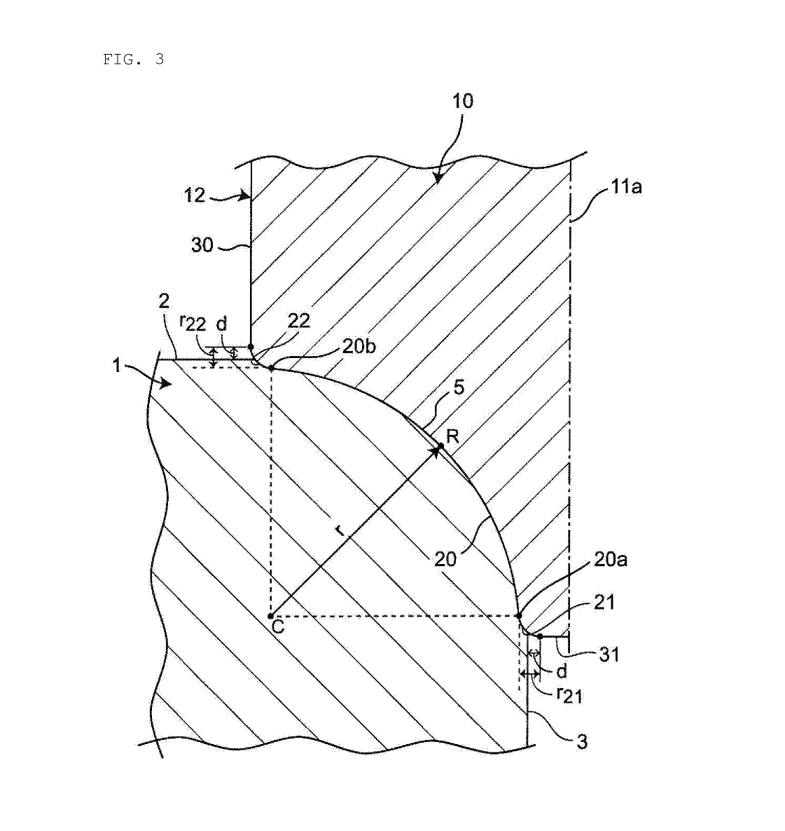

FIG. 1 is a perspective view showing an operation of a first embodiment of a cutting tool for a sputtering target of the present invention. FIG. 2 is a cross-sectional view showing the operation of the cutting tool for the sputtering target.

As shown in FIGS. 1 and 2, a cutting tool 10 for a sputtering target (hereinafter referred to as a cutting tool) chamfers a corner portion 4 formed between a sputtering surface 2 and a side surface 3 of a sputtering target 1 into an R plane 5.

The sputtering target 1 is formed in an elongated plate shape. The sputtering surface 2 is constituted of an upper surface defined by a short side direction and a long side direction. The side surface 3 is constituted of a surface defined by the short side direction or long side direction and the thickness direction. The corner portion 4 includes a side formed by the sputtering surface 2 and the side surface 3. The sputtering surface 2 may be constituted of a square top surface.

The sputtering target 1 may be formed in a disk shape. At this time, the sputtering surface 2 is constituted of a circular upper surface, and the side surface 3 is constituted of a circumferential surface between the circular upper surface and the circular lower surface. Alternatively, the sputtering target 1 may be formed in a cylindrical shape. At this time, the sputtering surface 2 is constituted of an outer circumferential surface of a cylindrical material, and the side surface 3 is constituted of a surface in the thickness direction of the cylindrical material.

During sputtering, inert gas ionized by the sputtering collides with the sputtering surface 2 of the sputtering target 1. Target atoms contained in the sputtering target 1 are sputtered and ejected from the sputtering surface 2 with which the ionized inert gas collides. The sputtered atoms are deposited on a substrate disposed facing the sputtering surface 2 to thereby form a thin film on the substrate.

The sputtering target 1 can be made from a material selected from the group consisting of metals, such as aluminum (Al), copper (Cu), chromium (Cr), iron (Fe), tantalum (Ta), titanium (Ti), zirconium (Zr), tungsten (W), molybdenum (Mo), niobium (Nb), and indium (In), and alloys thereof. However, the constituent material of the sputtering target 1 is not limited thereto. Specifically, the material of the sputtering target 1 for an electrode or wiring material is preferably Al, for example, more preferably Al having a purity of 99.99% or more, and particularly preferably Al having a purity of 99.999% or more. The high-purity Al is suitable as the material of the sputtering target 1 for an electrode or wiring material because of its high electrical conductivity. However, the higher the purity of Al, the softer the Al material becomes, and the more susceptible the Al material is to scratches. For this reason, the cutting tool for a sputtering target of the present invention can be suitably used especially for manufacturing a sputtering target that contains high-purity Al as a material. The thickness of the sputtering target 1 is usually approximately 10 to 25 mm.

Examples of the cutting tool 10 include an end mill, a radius cutter, an R cutter, and the like. Examples of a processing device on which the cutting tool 10 is installed include a type in which a sputtering target is fixed, and then a rotating cutting tool moves to chamfer the corner portion of the sputtering target with an outer circumferential surface of a blade portion 12, and a type in which a cutting tool is fixed without rotating with respect to a disk-shaped or cylindrical sputtering target, and then in this state, the sputtering target is rotated to have its corner portion chamfered with an outer circumferential surface of a blade portion 12.

The former type of processing device includes, for example, a milling machine, an NC milling machine, a machining center, and the like, whereas the latter type of processing device includes, for example, a lathe, an NC lathe, and the like.

The cutting tool 10 used in the processing device, such as a milling machine, an NC milling machine, or a machining center, has a shaft portion 11 with an axis 11a and the blade portion 12 provided at a tip end of the shaft portion 11. The central axis of the blade portion 12 coincides with the axis 11a of the shaft portion 11. The two or three blade portions 12 may be independently present around the axis 11a. Alternatively, the blade portion 12 may be continuously present around the axis 11a. In a case where a plurality of blade portions 12 are independently present, these blade portions are preferably arranged at equal intervals, for example, 180° intervals for two blade portions, 120° intervals for three blade portions, or 90° intervals for four blade portions, because this arrangement can easily create equal spacings between resultant work marks on the R plane 5. The blade portion 12 may be formed integrally with the shaft portion 11 or may be formed as a replaceable chip. As a material of the blade portion 12, a tungsten carbide-based material which is a cemented carbide or a high-speed steel called HSS (an alloy of a carbon steel as a base in combination with tungsten, molybdenum, chromium, vanadium, cobalt, or the like) is suitably used from the viewpoint of the durability and the prevention of any damage to the sputtering target due to chipping caused by impact during processing. In addition, a coating material, such as diamond or TiN, may be applied to the blade portion from the viewpoint of preventing abnormal discharge due to surface defects, including a burn-on defect.

The cutting tool 10 is arranged with respect to the sputtering target 1 such that the axis 11a coincides with the thickness direction of the sputtering target 1. Then, the cutting tool 10 is moved by the processing device in the long side direction (the extending direction of the corner portion 4) of the sputtering target 1 while rotating about the axis 11a, whereby the corner portion 4 of the sputtering target 1 is sequentially cut with the outer circumferential surface of the blade portion 12 of the cutting tool 10. In this way, the corner portion 4 is chamfered into the R plane 5. The width of the formed R plane 5 is usually 0.5 to 5 mm, and thus the radius of a main concave curved surface 20 is also usually 0.5 to 5 mm. The radius of the main concave curved surface is usually 0.02 times or more and 0.5 times or less, preferably 0.05 times or more and 0.4 times or less, and more preferably 0.1 times or more and 0.3 times or less the thickness of the sputtering target 1. When the relationship between the radius of the main concave curved surface 20 and the thickness of the sputtering target 1 satisfies the above-mentioned range, the R plane 5 that does not cause abnormal discharge can be formed, thereby preventing deposition of sputtered particles on a backing plate due to an excessively large area of the R plane 5.

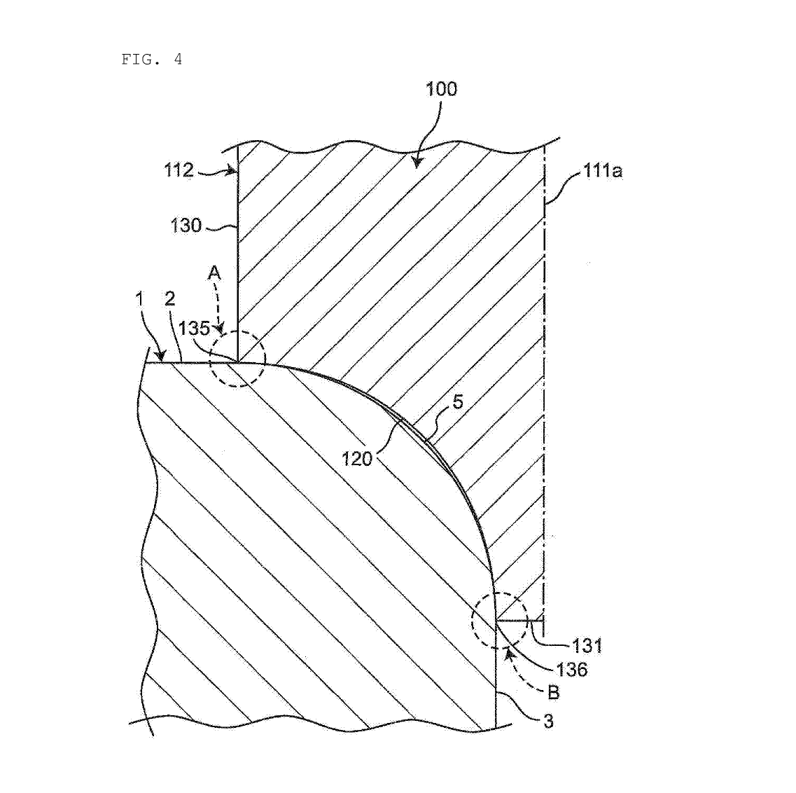

FIG. 3 is an enlarged cross-sectional view of FIG. 2. As shown in FIG. 3, an outer circumferential surface of the blade portion 12 includes, as viewed from its cross section along the axis 11a, the main concave curved surface 20 that extends from the trailing end to leading end of the blade portion 12, a first sub-convex curved surface 21 that is connected to a leading end 20a of the main concave curved surface 20, and a second sub-convex curved surface 22 that is connected to a trailing end 20b of the main concave curved surface 20. The main concave curved surfaces 20 and the first and second sub-convex curved surfaces 21 and 22 are positioned on the left and right sides with respect to the axis 11a in a line symmetrical manner. The leading end side refers to the side of the blade portion 12 in the direction along the axis 11a, and the trailing end side refers to the side of the shaft portion 11 in the direction along the axis 11a.

The outer circumferential surface of the blade portion 12 further includes a side surface 30 extending in parallel to the axis 11a. The blade portion 12 has a leading end surface 31 that intersects the axis 11a. The first sub-convex curved surface 21 is located between the main concave curved surface 20 and the leading end surface 31, and the second sub-convex curved surface 22 is located between the main concave curved surface 20 and the side surface 30. A connection point (20a) between (the leading end of) the main concave curved surface 20 and the first sub-convex curved surface 21 and a connection point (20b) between (the trailing end of) the main concave curved surface 20 and the second sub-convex curved surface 22 are inflection points, which are indicated by black-filled circles for easy understanding in the figure.

In other words, the first sub-convex curved surface 21 constitutes a first notched surface connected between the leading end 20a of the main concave curved surface 20 and the leading end surface 31. That is, the first notched surface is a surface obtained by chamfering the corner, which has been formed by connecting an extension line of the main concave curved surface 20 and an extension line of the leading end surface 31. The second sub-convex curved surface 22 constitutes a second notched surface connected between the trailing end 20b of the main concave curved surface 20 and the side surface 30. That is, the second notched surface is a surface obtained by chamfering the corner, which has been formed by connecting the extension line of the main concave curved surface 20 and an extension line of the side surface 30.

The main concave curved surface 20 and the first and second sub-convex curved surfaces 21 and 22 are circular arc surfaces. It is noted that the main concave curved surface 20 and the first and second sub-convex curved surfaces 21 and 22 may be elliptical arc surfaces, and are preferably substantially perfectly circular arc surfaces and more preferably perfectly circular arc surfaces.

In a case where the main concave curved surface 20 is a circular arc surface, an angle formed between a first straight line and a second straight line in the cross section along the axis 11a of the shaft portion of the cutting tool 10 shown in FIG. 3 is 70° or more and 90° or less, preferably 80° or more and 90° or less, and more preferably 90°, where the first straight line is a line that connects the leading end 20a of the main concave curved surface 20 with the center C of a circle (hereinafter, sometimes referred to as the center of the main concave curved surface 20) defined when the main concave curved surface 20 is regarded as the circular arc surface, and the second straight line is a line that connects the center C of the main concave curved surface 20 with the trailing end 20b of the main concave curved surface 20. Thus, the large main concave curved surface can be formed, thereby making it possible to form the large R plane 5 on the sputtering target 1, while preventing the formation of scratches on the R plane 5. To more reliably prevent the formation of scratches on the R plane 5, the leading end 20a of the main concave curved surface 20 is preferably positioned on a perpendicular line (a straight line parallel to the sputtering surface 2) drawn from the center C of the main concave curved surface 20 to the side surface 3 of the sputtering target 1 or on the inner side of the perpendicular line (on the main concave curved surface 20 side). The leading end 20a of the main concave curved surface 20 is more preferably positioned on the perpendicular line (the straight line parallel to the sputtering surface 2). Furthermore, the trailing end 20b of the main concave curved surface 20 is preferably positioned on a perpendicular line (a straight line parallel to the side surface 3) drawn from the center C of the main concave curved surface 20 to the sputtering surface 2 of the sputtering target 1, or on the inner side of the perpendicular line (on the main concave curved surface 20 side). The trailing end 20b of the main concave curved surface 20 is more preferably positioned on the perpendicular line (the straight line parallel to the side surface 3). Moreover, an angle formed between a straight line connecting the center point R of the R plane 5 on the circular arc and the center C of the main concave curved surface 20 and a perpendicular line drawn from the center C of the main concave curved surface 20 to the side surface 3 of the sputtering target 1 is preferably 45°.

When the main concave curved surface 20, the first sub-convex curved surface 21, and the second sub-convex curved surface 22 are circular arc surfaces, the radius of the main concave curved surface 20 is larger than each of the radius r₂₁ of the first sub-convex curved surface 21 and the radius r₂₂ of the second sub-convex curved surface 22. The radii r₂₁ and r₂₂ of the first and second sub-convex curved surfaces 21 and 22 are the same, but may be different from each other. Since the R plane 5 is formed by the main concave curved surface 20, the radius r of the R plane 5 coincides with the radius of the main concave curved surface 20. Each of the radii r₂₁ and r₂₂ of the first and second sub-convex curved surfaces 21 and 22 is 0.02 mm or more. From the viewpoint of preventing the formation of scratches on the R plane 5, each of the radii r₂₁ and r₂₂ is preferably 0.05 mm or more, and more preferably 0.1 mm or more. In addition, each of the radii r₂₁ and r₂₂ is normally 1 mm or less, and preferably 0.5 mm or less. Each of the radii r₂₁ and r₂₂ of the first and second sub-convex curved surfaces 21 and 22 is 35% or less of the radius r of the R plane 5 (main concave curved surface 20). From the viewpoint of smoothly processing the boundary between the sputtering surface 2 and the R plane 5, each of the radii r₂₁ and r₂₂ is preferably 25% or less, and more preferably 10% or less of the radius r of the R plane 5. Each of the radii r₂₁ and r₂₂ is preferably 0.5% or more and 25% or less, more preferably 1% or more and 20% or less, still more preferably 2% or more and 15% or less, and particularly preferably 2.5% or more and 10% or less of the radius r of the R plane 5 in order to suppress the shaking of a core of the cutting tool and vibrations (so-called chatter vibration) continuously generated between the cutting tool and the sputtering target, while preventing the formation of scratches on the R plane 5. The vibrations would otherwise cause the deterioration of the properties of a finished surface, the abnormal wear and tear of the cutting tool, and the failure of the processing device. By setting the radii r₂₁ and r₂₂ of the first and second sub-convex curved surfaces 21 and 22 within the above-mentioned range, the R surface 5 that has excellent finish surface properties with a low risk of occurrence of abnormal discharge can be formed, thereby extending the lifetime of the cutting tool and the processing device.

A gap d is provided between the trailing end of the second sub-convex curved surface 22 and the sputtering surface 2 of the sputtering target 1. The gap d is equal to or less than each of the radii r₂₁ and r₂₂ of the first and second sub-convex curved surfaces 21 and 22, and is usually 2% or more of the radius r of the R plane 5. For example, when the radius r of the R plane 5 is 3 mm, the gap d is 0.1 mm or more. A similar gap is also provided between the leading end of the first sub-convex curved surface 21 and the side surface 3 of the sputtering target 1.

According to the cutting tool 10, as viewed from the cross section along the axis 11a, the outer circumferential surface of the blade portion 12 has the main concave curved surface 20, the first sub-convex curved surface 21 connected to the leading end 20a of the main concave curved surface 20, and the second sub-convex curved surface 22 connected to the trailing end 20b of the main concave curved surface 20. Therefore, when the corner portion 4 of the sputtering target 1 is chamfered into the R plane 5 by cutting with the main concave curved surface 20, both ends of the main concave curved surface 20 are the first and second sub-convex curved surfaces 21 and 22, which can prevent the formation of scratches on the R plane 5. Even when the main concave curved surface 20, the first sub-convex curved surface 21, and the second sub-convex curved surface 22 are not circular arc surfaces, the above-mentioned relationship among the radii can be applied in the same manner by regarding the radius of the main concave curved surface 20, the radii r₂₁ and r₂₂ of the first sub-convex curved surface 21 and the second sub-convex curved surface 22, and the radius r of the R plane 5 as the widths of the respective curved surfaces in the direction of the axis 11a.

In short, the first and second sub-convex curved surfaces 21 and 22 are continuously formed on the main concave curved surface 20, whereby no corner (edge) is formed between the main concave curved surface 20 and the first and second sub-convex curved surfaces 21 and 22, resulting in a smooth R plane 5. Even if the corner portion 4 is cut by the first and second sub-convex curved surfaces 21 and 22 in addition to the main concave curved surface 20, the surface of the R plane 5 becomes smooth because the first and second sub-convex curved surfaces 21 and 22 have no edge.

When the sputtering target is made of metal or an alloy thereof, as its hardness is usually high, the shaking of the core in the cutting tool tends to occur due to a load applied when the corner is cut with the cutting tool rotating at a high speed to form the R plane. Since the cutting tool of the present application has the first notched surface and second notched surface mentioned above, the chamfering of the corner portion into the R plane with the cutting tool of the present application can prevent the formation of scratches on the R plane or the sputtering surface or side surface near the R plane.

In particular, since the R plane 5 can be prevented from having any scratch formed on the sputtering surface 2 side thereof, the occurrence of abnormal discharge can also be prevented when sputtering is performed for film deposition onto a substrate facing the sputtering surface 2, that is, when a high voltage is applied between the substrate and the sputtering target 1.

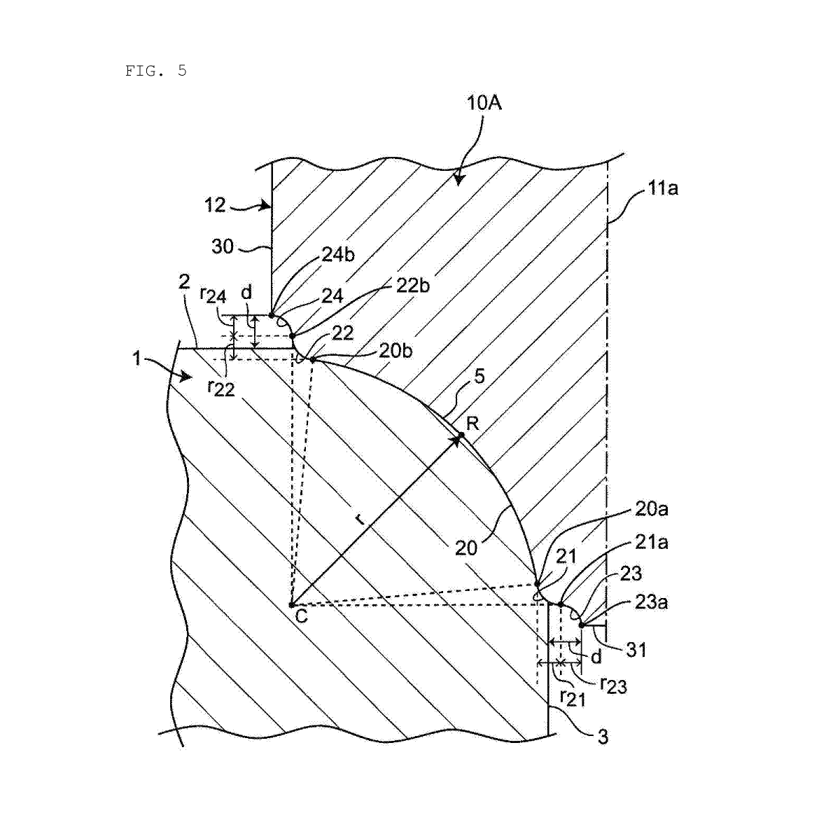

FIG. 4 shows a cutting tool 100 as a comparative example. On the outer circumferential surface of a blade portion 112 of the cutting tool 100, the first and second sub-convex curved surfaces 21 and 22 of the present invention are not provided, and only a main concave curved surface 120 is provided as viewed from the cross section along an axis 111a. That is, a first corner portion (edge) 135 is formed between the main concave curved surface 120 and a side surface 130, whereas a second corner portion (edge) 136 is formed between the main concave curved surface 120 and a leading end surface 131.

When the R plane 5 is formed on the sputtering target 1 using the cutting tool 100 of the comparative example, if there occurs slight variations in the positional accuracy of the sputtering target as a workpiece or slight shaking of a core of the cutting tool during processing, a scratch would be formed by the first corner portion 135 on the sputtering surface 2 side of the R plane 5 as indicated by an A part, or by the second corner portion 136 on the side surface 3 side of the R plane 5 as indicated by a B part. The depth of the scratch is usually approximately 10 to 30 μm. However, particularly, if such a scratch is formed on the sputtering surface 2 side of the R plane 5, the scratch may cause abnormal discharge when a high voltage is applied between the substrate and the sputtering target 1.

### Second Embodiment

FIG. 5 is a cross-sectional view showing an operation of a second embodiment of a cutting tool for a sputtering target of the present invention. The second embodiment differs from the first embodiment in the shape of the blade portion. The difference in the configuration therebetween will be described below. It is noted that in the second embodiment, the same reference numerals as those in the first embodiment denote the same configurations as in the first embodiment, and thus a description thereof is omitted.

As shown in FIG. 5, a cutting tool 10A further has, on the outer circumferential surface of the blade portion 12, a third sub-concave curved surface 23 connected to a leading end 21a of the first sub-convex curved surface 21 and a fourth sub-concave curved surface 24 connected to a trailing end 22b of the second sub-convex curved surface 22, in addition to the main concave curved surface 20 and the first and second sub-convex curved surfaces 21 and 22, as viewed from the cross section along the axis 11a. A connection point (21a) between the first sub-convex curved surface 21 and the third sub-concave curved surface 23 and a connection point (22b) between the second sub-convex curved surface 22 and the fourth sub-concave curved surface 24 are inflection points, which are indicated by black-filled circles for easy understanding in the drawing.

In other words, the first sub-convex curved surface 21 and the third sub-concave curved surface 23 constitute a first notched surface that is connected between the leading end 20a of the main concave curved surface 20 and the leading end surface 31. That is, the first notched surface is formed by chamfering the corner, which has been formed by connecting an extension line of the main concave curved surface 20 and an extension line of the leading end surface 31. Likewise, the second sub-convex curved surface 22 and the fourth sub-concave curved surface 24 constitute a second notched surface that is connected between the trailing end 20b of the main concave curved surface 20 and the side surface 30. That is, the second notched surface is formed by chamfering the corner, which has been formed by connecting the extension line of the main concave curved surface 20 and an extension line of the side surface 30.

The main concave curved surface 20, the first and second sub-convex curved surfaces 21 and 22, and the third and fourth sub-concave curved surfaces 23 and 24 are circular arc surfaces. It is noted that the main concave curved surface 20, the first and second sub-convex curved surfaces 21 and 22, and the third and fourth sub-concave curved surfaces 23 and 24 may be elliptical arc surfaces, and are preferably substantially perfectly circular arc surfaces and more preferably perfectly circular arc surfaces.

In a case where the main concave curved surface 20 is a circular arc surface, an angle formed between a first straight line and a second straight line in the cross section along the axis 11a of the shaft portion of the cutting tool 10 shown in FIG. 5 is 70° or more and 90° or less, preferably 80° or more and 90° or less, and more preferably 90°, where the first straight line is a line that connects the leading end 20a of the main concave curved surface 20 with the center C of the circle (the center of the main concave curved surface 20) defined when the main concave curved surface 20 is regarded as the circular arc surface, and the second straight line is a line that connects the center C of the main concave curved surface 20 with the trailing end 20b of the main concave curved surface 20. Thus, the large main concave curved surface can be formed, thereby forming the large R plane 5 on the sputtering target 1, while preventing the formation of scratches on the R plane 5. To further prevent the formation of scratches on the R plane 5, the leading end 20a of the main concave curved surface 20 is preferably positioned on a perpendicular line (a straight line parallel to the sputtering surface 2) drawn from the center C of the main concave curved surface 20 to the side surface 3 of the sputtering target 1 or on the inner side of the perpendicular line (on the main concave curved surface 20 side). The leading end 20a of the main concave curved surface 20 is more preferably positioned on the perpendicular line (the straight line parallel to the sputtering surface 2). Furthermore, the trailing end 20b of the main concave curved surface 20 is preferably positioned on a perpendicular line (a straight line parallel to the side surface 3) drawn from the center C of the main concave curved surface 20 to the sputtering surface 2 of the sputtering target 1, or on the inner side of the perpendicular line (on the main concave curved surface 20 side). The trailing end 20b of the main concave curved surface 20 is more preferably positioned on the perpendicular line (the straight line parallel to the side surface 3). Moreover, an angle formed between a straight line connecting the center point R of the R plane 5 on the circular arc and the center C of the main concave curved surface and a perpendicular line drawn from the center C of the main concave curved surface 20 to the side surface 3 of the sputtering target 1 is preferably 45°.

When the main concave curved surface 20, the first and second sub-convex curved surfaces 21 and 22, and the third and fourth sub-concave curved surfaces 23 and 24 are circular arc surfaces, each of the radius r₂₃ of the third sub-concave curved surface 23 and the radius r₂₄ of the fourth sub-concave curved surface 24 is smaller than the radius of the main concave curved surface 20. The radii r₂₁ and r₂₂ of the first and second sub-convex curved surfaces 21 and 22 and the radii r₂₃ and r₂₄ of the third and fourth sub-concave curved surfaces 23 and 24 are the same, but may be different from one another. The R plane 5 is formed by the main concave curved surface 20, so that the radius r of the R plane 5 coincides with the radius of the main concave curved surface 20. The sum r₂₂+r₂₄ of the radii of the second sub-convex curved surface 22 and the fourth sub-concave curved surface (similarly, the sum r₂₁+r₂₃ of the radii of the first sub-convex curved surface 21 and the third sub-concave curved surface 23) is 0.02 mm or more. From the viewpoint of preventing the formation of scratches on the R plane 5, this sum is preferably 0.05 mm or more, and more preferably 0.1 mm or more. In addition, this sum is usually 1 mm or less and preferably 0.5 mm or less. Meanwhile, the sum r₂₂+r₂₄ (similarly, r₂₁+r₂₃) is 35% or less of the radius r of the R plane 5 (main concave curved surface 20), and in order to smoothly process the boundary between the sputtering surface 2 and the R plane 5, the sputtering surface 2 preferably has a shape that intersects the third and fourth sub-concave curved surfaces 23 and 24. The sum r₂₂+r₂₄ (similarly, r₂₁+r₂₃) is preferably 0.5% or more and 25% or less, more preferably 1% or more and 20% or less, still more preferably 2% or more and 15% or less, and particularly preferably 2.5% or more and 10% or less of the radius r of the R plane 5 in order to suppress the shaking of the core of the cutting tool as well as vibrations (so-called chatter vibration) continuously generated between the cutting tool and the sputtering target while preventing the formation of scratches on the R plane 5. By setting the sum r₂₂+r₂₄ and the sum r₂₁+r₂₃ within the above-mentioned respective ranges, the R plane 5 that has excellent finish surface properties with a low risk of occurrence of abnormal discharge can be formed, thereby extending the lifetime of the cutting tool and the processing device.

A gap d is provided between a trailing end 24b of the fourth sub-concave curved surface 24 and the sputtering surface 2 of the sputtering target 1. The gap d is equal to or less than the sum (r₂₂+r₂₄, r₂₁+r₂₃) of the radii of the sub-convex curved surface and the sub-concave curved surface, and is usually 2% or more of the radius r of the R plane 5.

For example, when the radius r of the R plane 5 is 3 mm, the gap d is 0.1 mm or more. A similar gap d is also provided between a leading end 23a of the third sub-concave curved surface 23 and the side surface 3 of the sputtering target 1.

According to the cutting tool 10A, the outer circumferential surface of the blade portion 12 further includes the third sub-concave curved surface 23 and the fourth sub-concave curved surface 24, and thus can more reliably prevent the formation of scratches on the R plane 5. As shown in FIG. 5A, the above-mentioned effect can be effectively exhibited by setting the gap d on the fourth sub-concave curved surface 24 side larger than each of the radius r₂₂ of the second sub-convex curved surface 22 and the radius r₂₄ of the fourth sub-concave curved surface 24. It is noted that the above-mentioned effect can also be exhibited by setting the gap d on the third sub-concave curved surface 23 side larger than each of the radius r₂₁ of the first sub-convex curved surface 21 and the radius r₂₃ of the third sub-concave curved surface 23.

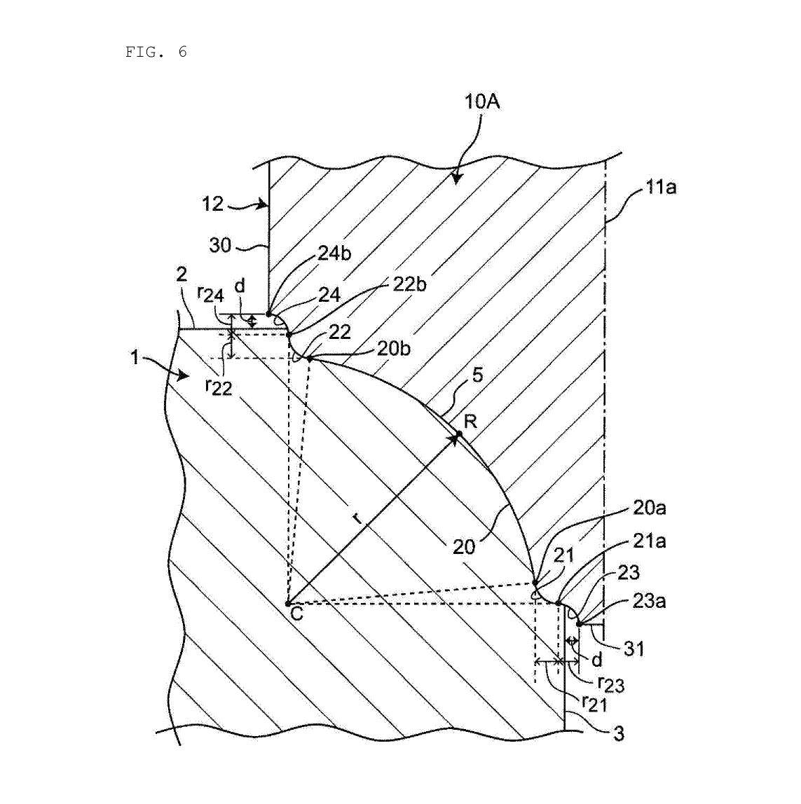

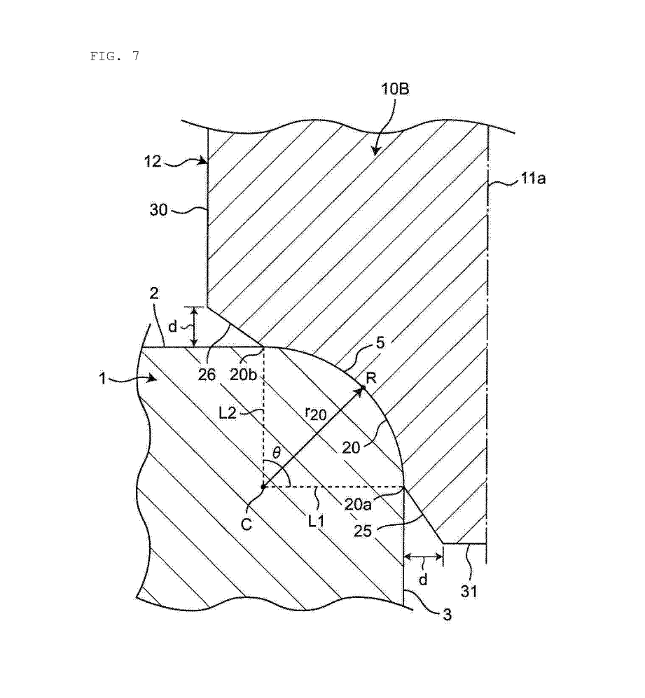

As shown in FIG. 6, when the gap d on the fourth sub-concave curved surface 24 side is set smaller than each of the radius of curvature r₂₂ of the second sub-convex curved surface 22 and the radius r₂₄ of the fourth sub-concave curved surface 24, an angle formed by the R plane 5 and the sputtering surface 2 of the sputtering target 1 is closer to a flat angle than that obtained in the first embodiment. Thus, the occurrence of abnormal discharge during sputtering can be prevented more reliably, in addition to the effect of preventing the formation of scratches on the R plane 5. It is noted that the above-mentioned effect can also be exhibited by setting the gap d on the third sub-concave curved surface 23 side smaller than each of the radius r₂₁ of the first sub-convex curved surface 21 and the radius r₂₃ of the third sub-concave curved surface 23.

Even when the main concave curved surface 20, the first and second sub-convex curved surfaces 21 and 22 and the third and fourth sub-concave curved surfaces 23 and 24 are not circular arc surfaces, the above-mentioned relationship among the radii can be applied in the same manner by regarding the radius of the main concave curved surface 20, the radii r₂₁ and r₂₂ of the first and second sub-convex curved surfaces 21 and 22, the radii r₂₃ and r₂₄ of the third and fourth sub-concave curved surfaces 23 and 24, and the radius r of the R plane 5 as the widths of the respective curved surfaces in the direction of the axis 11a.

### Third Embodiment

FIG. 7 is a cross-sectional view showing an operation of a third embodiment of a cutting tool for a sputtering target of the present invention. The third embodiment differs from the first embodiment in the shape of the blade portion. The difference in the configuration therebetween will be described below. It is noted that in the third embodiment, the same reference numerals as those in the first embodiment denote the same configurations as in the first embodiment, and thus a description thereof is omitted.

As shown in FIG. 7, an outer circumferential surface of the blade portion 12 of a cutting tool 10B includes, as viewed from its cross section along the axis 11a, a first inclined surface 25 serving as the first notched surface connected to the leading end 20a of the main concave curved surface 20 and a second inclined surface 26 serving as the second notched surface connected to the trailing end 20b of the main concave curved surface 20. The first and second inclined surfaces 25 and 26 are flat surfaces.

Therefore, when the corner portion 4 of the sputtering target 1 is chamfered into the R plane 5 by cutting with the main concave curved surface 20, both ends of the main concave curved surface 20 are the first and second inclined surfaces 25 and 26, thereby making it possible to prevent the formation of scratches on the R plane 5. In addition, since the first and second inclined surfaces 25 and 26 are flat surfaces, scratches can be prevented from being formed on the R plane 5 due to the inclined surfaces 25 and 26 themselves.

In a case where the main concave curved surface 20 is a circular arc surface, an angle θ formed between a first straight line L1 and a second straight line L2 in the cross section along the axis 11a is preferably 70° or more and 90° or less, more preferably 80° or more and 90° or less, and still more preferably 90°, where the first straight line L1 is a line that connects the leading end 20a of the main concave curved surface 20 with the center C of the circle (the center of the main concave curved surface 20) defined when the main concave curved surface 20 is regarded as the circular arc surface, and the second straight line L2 is a line that connects the center C of the main concave curved surface 20 with the trailing end 20b of the main concave curved surface 20. Thus, the large main concave curved surface 20 can be formed, so that the large R plane 5 can be formed on the sputtering target 1, while preventing the formation of scratches on the R plane 5. The radius of the R plane 5 coincides with the radius r₂₀ of the main concave curved surface 20. To further prevent the formation of scratches on the R plane 5, the leading end 20a of the main concave curved surface 20 is preferably positioned on a perpendicular line (a straight line parallel to the sputtering surface 2) drawn from the center C of the main concave curved surface 20 to the side surface 3 of the sputtering target 1, or on the inner side of the perpendicular line (on the main concave curved surface 20 side). The leading end 20a of the main concave curved surface 20 is more preferably positioned on the perpendicular line (the straight line parallel to the sputtering surface 2). Furthermore, the trailing end 20b of the main concave curved surface 20 is preferably positioned on a perpendicular line (a straight line parallel to the side surface 3) drawn from the center C of the main concave curved surface 20 to the sputtering surface 2 of the sputtering target 1, or on the inner side of the perpendicular line (on the main concave curved surface 20 side). The trailing end 20b of the main concave curved surface 20 is more preferably positioned on the perpendicular line (the straight line parallel to the side surface 3). Moreover, an angle formed between a straight line connecting the center point R of the R plane 5 on the circular arc and the center C of the main concave curved surface 20 and a perpendicular line drawn from the center C of the main concave curved surface 20 to the side surface 3 of the sputtering target 1 is preferably 45°.

A gap d provided between the trailing end of the second inclined surface 26 and the sputtering surface 2 of the sputtering target 1 is 0.05 mm or more, and from the viewpoint of preventing the formation of scratches on the R plane 5, the gap d is preferably 0.1 mm or more. In addition, the gap d is normally 0.5 mm or less. An angle formed between the second inclined surface 26 and the sputtering surface 2 is 1° or more. From the viewpoint of preventing the formation of scratches on the R plane 5, this angle is preferably 2° or more, more preferably 3° or more, still more preferably 10° or more, and particularly preferably 20° or more. Furthermore, in order to more reliably prevent the occurrence of abnormal discharge during sputtering, this angle is less than 90°, preferably 60° or less, more preferably 45° or less, still more preferably 30° or less, and particularly preferably 25° or less. Thus, an angle formed between the sputtering surface 2 and the R plane 5 of the sputtering target 1 is closer to a flat angle. Similarly, a gap d provided between the leading end of the first inclined surface 25 and the side surface 3 of the sputtering target 1 is 0.05 mm or more, and from the viewpoint of preventing the formation of scratches on the R plane 5, the gap d is preferably 0.1 mm or more. In addition, the gap d is normally 0.5 mm or less. An angle formed between the first inclined surface 25 and the side surface 3 is 1° or more. From the viewpoint of preventing the formation of scratches on the R plane 5, this angle is preferably 2° or more, more preferably 3° or more, still more preferably 10° or more, and particularly preferably 20° or more. Furthermore, in order to more reliably prevent the occurrence of abnormal discharge during sputtering, this angle is less than 90°, preferably 60° or less, more preferably 45° or less, still more preferably 30° or less, and particularly preferably 25° or less. Thus, the angle formed between the sputtering surface 2 and the R plane 5 of the sputtering target 1 is closer to a flat angle. Therefore, the first and second inclined surfaces 25 and 26 can be formed in a shape that makes the R plane 5 less susceptible to scratches and which is less likely to cause abnormal discharge during sputtering. The angle formed between the second inclined surface 26 and the sputtering surface 2 or the angle formed between the first inclined surface 25 and the side surface 3 is set to 1° or more and 30° or less, resulting in a decreased distance between the sputtering target 1 and either an intersection point of the second inclined surface 26 and the side surface 30 or an intersection point of the first inclined surface 25 and the leading end surface 31. This can suppress vibration (so-called chatter vibration) continuously generated between the cutting tool and the sputtering target, so that the R plane 5 having excellent finish surface properties with a low risk of occurrence of abnormal discharge can be formed, thereby extending the lifetime of the cutting tool and the processing device.

When the main concave curved surface 20 is a circular arc surface, the radius of the main concave curved surface 20 is larger than each of the lengths of the first and second inclined surfaces 25 and 26. The lengths of the first and second inclined surfaces 25 and 26 are the same, but may be different from each other. Since the R plane 5 is formed by the main concave curved surface 20, the radius r of the R plane 5 coincides with the radius of the main concave curved surface 20. Each of the lengths of the first and second inclined surfaces 25 and 26 is 0.02 mm or more. From the viewpoint of preventing the formation of scratches on the R plane 5, each length of the first and second inclined surfaces 25 and 26 is preferably 0.05 mm or more. In addition, this length is normally 1 mm or less, and preferably 0.5 mm or less. Each of the lengths of the first and second inclined surfaces 25 and 26 is normally 35% or less, preferably 0.5% or more and 25% or less, more preferably 1% or more and 20% or less, still more preferably 2% or more and 15% or less, and particularly preferably 2.5% or more and 10% or less of the radius r of the R plane 5 (main concave curved surface 20). The first and second inclined surfaces 25 and 26 are formed so that their lengths fall within the above-mentioned range, thereby making it possible to suppress the shaking of the core of the cutting tool and vibration (so-called chatter vibration) continuously generated between the cutting tool and the sputtering target, while preventing the formation of scratches on the R plane 5. Thus, the R plane 5 having excellent finish surface properties with a low risk of occurrence of abnormal discharge can be formed, thereby extending the lifetime of the cutting tool and the processing device.

The present invention is not limited to the above-mentioned embodiments, and various modifications and changes can be made to these embodiments without departing from the scope of the present invention. For example, the respective features of the first to third embodiments may be combined variously.

In the first to third embodiments, the cutting tool is placed with respect to the sputtering target 1 such that the axis 11a coincides with the thickness direction of the sputtering target 1. However, the axis 11a may be placed in parallel to the sputtering surface 2 and then moved along the long side direction of the sputtering target 1 (the extending direction of the corner portion 4), whereby the corner portion 4 of the sputtering target 1 may be cut with the blade portion 12 of the cutting tool. When the axis 11a of the cutting tool coincides with the thickness direction (perpendicular to the sputtering surface) of the sputtering target 1 or is in parallel with the sputtering surface 2, such a cutting tool can suppress the occurrence of shaking of the core of the cutting tool or vibrations (so-called chatter vibration) continuously generated between the cutting tool and the sputtering target, during chamfering.

In the above-mentioned embodiments, a processing device, such as a milling machine, an NC milling machine, or a machining center, has been described by way of example. In this processing device, the corner portion of the sputtering target is chamfered by moving the rotating cutting tool while fixing the sputtering target.

In contrast, when the sputtering target has a disk shape or a cylindrical shape, a processing device (lathe, NC lathe, or the like) may be used to perform chamfering. In this processing device, the corner portion of the sputtering target may be chamfered by rotating the sputtering target while fixing the cutting tool without rotation about the axis. The shape of the blade portion of the cutting tool used in the processing device, such as a lathe or an NC lathe, may have a concave curved surface similar to that used in the processing device, such as a milling machine.

When the sputtering target has a disk shape, the chamfering can be performed by rotating the sputtering target about a straight line, as a central axis, which is perpendicular to the sputtering surface and passes through the center of the circular sputtering surface, and then bringing the cutting tool close to or into contact with the corner portion of the sputtering target.

When the sputtering target has a cylindrical shape, the chamfering can be performed by rotating the sputtering target about a straight line, as a central axis, which is parallel to its outer circumferential surface and passes through the center of its side surface, and then bringing the cutting tool close to or into contact with the corner portion of the sputtering target.

In chamfering the disk-shaped or cylindrical sputtering target, the shaft portion of the cutting tool may be arranged perpendicular to the sputtering surface or to the side surface of the sputtering target when bringing the cutting tool close to or into contact with the sputtering target. This arrangement may be appropriately selected depending on the shape of the sputtering target and the type of the processing device. In the way mentioned above, the shaft portion of the cutting tool is brought close to or into contact with the corner portion of the sputtering target during the chamfering process, thereby making it possible to suppress the occurrence of shaking of the core of the cutting tool or vibrations (so-called chatter vibration) continuously generated between the cutting tool and the sputtering target.

In the first to third embodiments, the concave curved surface or the convex curved surface is a circular arc surface as viewed from its cross section, but may be a substantially circular arc or curved surface. In the first to third embodiments, the side surface 30 of the blade portion 12 is parallel to the axis 11a by way of example. However, the side surface 30 may not be parallel to the axis 11a, and may have a curved surface or a cross-section that intersects the axis 11a when extended as long as the side surface 30 does not interfere with the chamfering process.

In the above-mentioned embodiment, a maximum of two curved surfaces is formed in series to be continuous to one end of the main concave curved surface. However, three or more curved surfaces may be formed in series. It is noted that if the number of curved surfaces formed in series is increased, the size of the cutting tool becomes large, and because of this, the number of curved surfaces formed in series is preferably at most two.

When the sputtering target is constituted of an elongated body of, for example, 2 m to 3 m in length, variations in process quality, such as process distortion due to the cutting process, tend to occur for each product of the sputtering target. Suppose that the radius of curvature of the concave curved surface of the blade portion is set to the same size as the target radius of curvature of the target R plane, and then the corner portion of the sputtering target is chamfered with the concave curved surface of the blade portion. In this case, both ends of the concave curved surface of the blade portion may be caught in the sputtering target due to variations in process quality, such as process distortion for each product of the sputtering target, and consequently many scratches are more likely to be formed. However, according to the present invention, any scratch can be appropriately prevented from being formed on the R plane, even if the position of the concave curved surface of the blade portion deviates from the target processing position when chamfering the corner portion of the sputtering target.

The number of the blade portions that are installed around the axis 11a of the cutting tool for a sputtering target of the present invention is preferably 2 to 4 for a cutting tool used in a processing device, such as a milling machine, an NC milling machine, or a machining center, or preferably 1 for a cutting tool used in a processing device, such as a lathe or an NC lathe.

As applicable processing conditions, for a cutting tool used in a processing device, such as a milling machine, an NC milling machine, or a machining center, it is preferable to set the rotation speed to 100 to 10,000 rpm and the tool feed speed to 100 to 3000 mm/min. In contrast, for a cutting tool used in a processing device, such as a lathe or an NC lathe, usually, the rotation speed may be 5 to 1000 rpm and the tool feed speed may be 1 mm/revolution or less, although they are appropriately adjusted depending on the material of the sputtering target.

The processing method of the present invention is characterized in that the above-mentioned cutting tool for a sputtering target is used to chamfer the corner portion formed between the sputtering surface and the side surface of the sputtering target, into the R plane.

As an embodiment of the processing method of the present invention, there is proposed a method for chamfering a corner portion formed between a sputtering surface and a side surface of a sputtering target, into an R surface, wherein the corner portion is chamfered into the R plane through cutting by bringing an outer circumferential surface of the blade portion of the cutting tool into contact with the corner portion of the sputtering target, while rotating the above-mentioned cutting tool for a sputtering target about the axis of the shaft portion.

As another embodiment of the processing method of the present invention, there is also proposed a method for chamfering a corner portion formed between a sputtering surface and a side surface of a disk-shaped or cylindrical sputtering target, into an R surface, wherein the corner portion is chamfered into the R plane through cutting by bringing an outer circumferential surface of the blade portion of the cutting tool for a sputtering target into contact with the corner portion of the sputtering target, while rotating the sputtering target.

In the processing method of the present invention, the specific processing device and processing conditions are as described in the embodiments of the above-mentioned cutting tool for a sputtering target.

A manufacturing method of a sputtering target product of the present invention includes a step of processing a sputtering target using the processing method mentioned above.

Specifically, for example, a target material is formed into a rectangular parallelepiped shape or a cylindrical shape through melting or casting, and then the formed target material is subjected to plastic working, such as rolling, forging, or extrusion, thereby obtaining a plate-shaped, disk-shaped, or cylindrical sputtering target. Subsequently, the thus-obtained sputtering target is processed by the above-mentioned processing method suitable for the corresponding shape. At this time, the surface of the sputtering target may be finished as necessary. Thereafter, the processed sputtering target is joined to a backing plate to manufacture a sputtering target product. It is noted that the backing plate may be omitted, and the sputtering target product itself may be manufactured using the processed sputtering target only.

The backing plate is made of a conductive material, such as a metal or an alloy thereof. Examples of the metal include copper, aluminum, titanium, and the like. Solder, for example, is used to join the sputtering target and the backing plate. Example of the solder material include metals, such as indium, tin, zinc, and lead, and alloys thereof.

The manufacturing method of the sputtering target product utilizes the above-mentioned processing method and thereby can obtain the sputtering target product having improved quality.

### DESCRIPTION OF REFERENCE NUMERALS

1 Sputtering target
2 Sputtering surface
3 Side surface
4 Corner portion
5 R plane
10, 10A, 10B Cutting tool for a sputtering target
11 Shaft portion
11a Axis
12 Blade portion
20 Main concave curved surface
21 First sub-convex curved surface (first notched surface)
22 Second sub-convex curved surface (second notched surface)
23 Third sub-concave curved surface (first notched surface)
24 Fourth sub-concave curved surface (second notched surface)
25 First inclined surface (first notched surface)
26 Second inclined surface (second notched surface)
30 Side surface
31 Leading end surface
C Center of the main concave curved surface 20
R Center point on the R plane and on the circular arc of the main concave curved surface 20
L1 First straight line
L2 Second straight line
θ Angle
r₂₀ Radius of the main concave curved surface

1. A cutting tool for a sputtering target that is used to chamfer a corner portion formed between a sputtering surface and a side surface of a sputtering target, into an R plane, the cutting tool comprising:
a shaft portion; and a blade portion provided at a tip end of the shaft portion, wherein
as viewed from a cross section along an axis of the shaft portion, the blade portion includes: a side surface extending along the axis;
a leading end surface intersecting the axis; a main concave curved surface positioned between the side surface and the leading end surface, the main concave curved surface extending from a trailing end to a leading end; a first notched surface connected between the leading end of the main concave curved surface and the leading end surface; and a second notched surface connected between the trailing end of the main concave curved surface and the side surface.

2. The cutting tool for a sputtering target according to claim 1, wherein, as viewed from the cross section along the axis of the shaft portion, the first notched surface includes a first sub-convex curved surface or a first inclined surface that is connected to the leading end of the main concave curved surface, and the second notched surface includes a second sub-convex curved surface or a second inclined surface that is connected to the trailing end of the main concave curved surface.

3. The cutting tool for a sputtering target according to claim 2, wherein, as viewed from the cross section along the axis of the shaft portion, the first notched surface includes the first sub-convex curved surface connected to the leading end of the main concave curved surface, and the second notched surface includes the second sub-convex curved surface connected to the trailing end of the main concave curved surface.

4. The cutting tool for a sputtering target according to claim 3, wherein, as viewed from the cross section along the axis, the first notched surface further includes a third sub-concave curved surface connected to a leading end of the first sub-convex curved surface, and the second notched surface further includes a fourth sub-concave curved surface connected to a leading end of the second sub-convex curved surface.

5. The cutting tool for a sputtering target according to claim 1, wherein, as viewed from the cross section along the axis of the shaft portion, the first notched surface includes a first inclined surface connected to the leading end of the main concave curved surface, and the second notched surface includes a second inclined surface connected to the trailing end of the main concave curved surface.

6. A processing method of a sputtering target for chamfering a corner portion formed between a sputtering surface and a side surface of the sputtering target, into an R plane, wherein
the corner portion is chamfered into the R plane through cutting by bringing an outer circumferential surface of the blade portion of the cutting tool for a sputtering target according to claim 1, into contact with the corner portion of the sputtering target, while rotating the cutting tool about the axis of the shaft portion.

7. A processing method of a disk-shaped or cylindrical sputtering target for chamfering a corner portion formed between a sputtering surface and a side surface of the sputtering target, into an R plane, wherein
the corner portion is chamfered into the R plane through cutting by bringing an outer circumferential surface of the blade portion of the cutting tool for a sputtering target according to claim 1, into contact with the corner portion of the sputtering target, while rotating the sputtering target.

8. A manufacturing method of a sputtering target product, comprising a step of processing a sputtering target by the processing method according to claim 6.
